(19) United States
(12) Patent Application Publication
(10) Pub. No.: US 2011/0124195 A1
(43) Pub. Date: May 26, 2011

(54) Chemical Mechanical Polishing Composition Containing Polysilicon Polish Finisher

(75) Inventors: Hyu-Bum Park, Chungcheongnam-do (KR); Dae-Sung Kim, Seoul (KR); Jong-Kwan Park, Gongju-si (KR); Jung-Ryul Ahn, Daejeon (KR)

(73) Assignee: TECHNO SEMICHEM CO., LTD., Seongnam-si (KR)

(21) Appl. No.: 13/055,322

(22) PCT Filed: Jul. 22, 2009
(86) PCT No.: PCT/KR09/04055

§ 371 Date: Jan. 21, 2011

(30) Foreign Application Priority Data
Jul. 24, 2008 (KR) 10-2008-0072072

(51) Int. Cl. H01L 21/306; C09K 13/00; C09K 13/02; C09K 13/06

(52) U.S. Cl. 438/693; 252/79.1; 252/79.5; 252/79.4; 257/E21.23

(57) ABSTRACT

Provided are a chemical mechanical polishing (CMP) composition used for polishing a semiconductor device which contains polysilicon film and insulator, and a chemical mechanical polishing method thereof. The CMP composition is especially useful in a isolation CMP process for semiconductor devices. Provided is a highly selective CMP composition containing a polysilicon polish finisher which can selectively polish semiconductor insulators since it uses a polysilicon film as a polish finishing film.

### TECHNICAL FIELD

The following disclosure relates to a highly selective chemical mechanical polishing composition useful in a planarization process of a semiconductor substrate having a polishing finisher film and an insulation film to be polished, among semiconductor device manufacturing technologies, as well as a chemical mechanical polishing method using the same.

### BACKGROUND

With miniaturization of a semiconductor device and increase in density thereof, techniques to form micro patterns having correspondingly decreased size are employed, and therefore, a surface structure of a semiconductor device is more complex and a step height (or a step depth) between surface films of the semiconductor device is increased. With regard to fabrication of semiconductor devices, a chemical mechanical polishing (referred to as ‘CMP’) process is generally used globally as a planarization technique to remove a step depth from a specific film formed on a semiconductor substrate.

As described above, due to high density semiconductor device, techniques to form micro patterns with decreased size are employed. Additionally, high integration of semiconductor devices and strict standards for semiconductor manufacturing processes cause a requirement for high planarization of a semiconductor substrate having various insulating films. For instance, a substrate used for manufacturing a semiconductor device, which has a polish finisher film such as a silicon nitride film as well as an insulating film such as a silicon oxide film, is treated by CMP. In particular, in order to maintain a predetermined thickness of an isolation insulating film in a shallow trench isolation (referred to as ‘STI’) process of a bottom part of a semiconductor device, a CMP process using a polish finisher film such as silicon nitride is employed. However, due to miniaturization of patterns, an allowable range for dishing an insulating film part or erosion of a polish finisher film tends to decrease. Therefore, in order to solve the foregoing defects, there is a demand for developing a higher selective CMP composition with high selectivity of a polishing rate.

With regard to the CMP composition used for STI of a bottom part of a semiconductor device, a polish finisher film based on polysilicon shows a considerably reduced polishing rate, compared to silicon nitride films conventionally used as the polish finisher film, thereby increasing a polishing selectivity (a polishing rate of an insulating film: a polishing rate of a polish finisher film). Although a polishing selectivity (a polishing rate of an insulating film: a polishing rate of silicon nitride) typically ranges from 30:1 to 40:1, higher selectivity of more than 50:1 is required to achieve excellent planarization features.

For example, Korean Laid-Open Patent Publication No. 2008-0003485 discloses CMP slurry which includes polyethyleneglycol as a polymer additive as well as a ceria abrasive and contains acid in order to maintain a pH range of 2 to 7. Korean Patent No. 0,829,594 discloses a CMP composition containing tri-block copolymer as a nonionic surfactant adsorbed to a surface of a polysilicon film to decrease a polishing rate, which comprises a first polyethylene oxide repeat unit, a polypropylene oxide repeat unit and a second polyethylene oxide repeat unit. Korean Patent No. 0,793,240 discloses a CMP composition including a nonionic surfactant based on polyoxyethylene ether or polyoxyethylene ester compounds as an additive adsorbed to a surface of a hydrophobic film to protect the same from ceria abrasives.

However, a conventional CMP composition used for polishing an insulating film, which includes polysilicon film as a polish finisher film, has poor protective performance of the polysilicon film which in turn includes difficulties in inhibiting defects in the polysilicon film with a low hardness, and poor cleanliness after CMP, thus requiring improvement.

### SUMMARY

An embodiment of the present invention is directed to providing a chemical mechanical polishing (CMP) composition, with advantages including: high polishing selectivity of an insulating film as for a polysilicon film such that deviation in electrical characteristics of a device may be reduced during CMP of a substrate having an insulating film and a polysilicon film as a polish finisher film; protection of the polysilicon film having a low hardness to sufficiently inhibit occurrence of defects such as scratches; improved cleanliness after CMP, and so forth.

More particularly, an object of the present invention is to provide a CMP composition applicable to a CMP process using a polish finisher film made of, for example, polysilicon, in order to maintain a predetermined thickness of an insulating film in a STI process of a bottom part of a semiconductor device.

Another object of the present invention is to provide a polishing method of a semiconductor substrate having an insulating film and a polysilicon film, including: using the CMP composition that prevents polishing of the polysilicon film and inhibits surface defects in the polysilicon film with a low hardness, as described above.

In order to accomplish the foregoing purposes, the present invention provides a CMP composition including abrasive particles and a polish finisher to prevent polishing of a polysilicon film and a method for polishing a semiconductor substrate using the foregoing CMP composition.

When a polishing rate of a polysilicon film as a polish finisher film in a pattern wafer is lower than that of an insulating film as a subject to be polished, a thickness of the insulating film after polishing may be uniform throughout all regions of the wafer while decreasing a deviation in thickness of the insulating film in respects to a pattern density, thereby uniformly maintaining electrical characteristics of the wafer. Among characteristics of a polishing slurry, a selectivity (a ratio of an insulating film polishing rate: a polysilicon polishing rate) may be more than 50:1 while a polishing rate of a polish finisher film (i.e., a polysilicon film) may be less than 100Å/min. It is more preferable that the selectivity is more than 100:1 and the polishing rate of the polish finisher film is less than 50Å/min. Most preferably, the selectivity is 200:1 or more and the polishing rate of the polish finisher film is 30Å/min or less.

As described above, in one general aspect, there is provided a CMP composition including a polysilicon polish finisher to prevent polishing of a polysilicon film, in particular, wherein the polish finisher may be selected from: 1) a compound that has a branched molecule with a molecular structure comprising at least three branches, and contains nitrogen or carbon as a center atom and at least three ethylene oxide groups (—CH₂CH₂O—) in a molecule, and its salt or a mixture thereof; 2) a compound having at least one functional group to be ionized in an aqueous solution state as well as at least three ethylene oxide groups (—CH₂CH₂O—), and its salt or a mixture thereof; or a combination of 1) and 2).

The polysilicon polish finisher according to the present invention has various advantages such as: excellent adsorption to a polysilicon film which in turn results in superior polishing prevention performance of a polysilicon film; formation of a uniform and rigid protective film on a surface of the polysilicon film, thereby inhibiting surface defects in the polysilicon film which has lower hardness than that of the insulating film during a CMP process. Moreover, the polysilicon polish finisher according to the present invention may be effectively removed using a cleaning solution containing deionized water during a washing process after CMP.

Hereinafter, the present invention will be described in detail.

Unless the context otherwise indicates, technical and/or scientific terms used herein have meanings understood by a person having an ordinary knowledge in the technical field to which the present invention pertains. Further, repeated description of the same technical configurations and/or functions as known by conventional technologies may be omitted.

The present invention relates to a CMP composition used in a planarization process of a semiconductor substrate having both an insulating film and a polysilicon film as a polish finisher film, among semiconductor manufacturing technologies, and a CMP method using the same.

The CMP composition for an insulating film-containing substrate according to the present invention may include (i) a polysilicon polish finisher selected from: 1) a compound that has a branched molecule with a molecular structure comprising at least three branches, and contains nitrogen or carbon as a center atom and at least three ethylene oxide groups (—CH₂CH₂O—) in a molecule, and its salt or a mixture thereof; 2) a compound having at least one functional group to be ionized in an aqueous solution as well as at least three ethylene oxide groups (—CH₂CH₂O—), and its salt or a mixture thereof; or a mixture of 1) and 2), and (ii) at least one type of abrasive particles selected from silica, cerium oxide, zirconium oxide, aluminum oxide and zeolite.

Preferably, the polysilicon polish finisher is selected from compounds satisfying both of the foregoing conditions (1) and (2), that is, selected from a compound which has 3 to 10,000 ethylene oxide groups (—CH₂CH₂O—) in a molecule and contains a branched molecule with a molecular structure comprising at least three branches, nitrogen or carbon as a center atom, and at least one functional group to be ionized in an aqueous solution state, as well as its salt or a mixture thereof.

The polysilicon polish finisher particularly includes any one of the compounds represented by Formulae 1 to 3 and mixtures thereof:

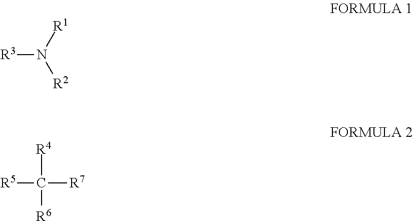

[in Formulae 1 and 2, R¹ and R⁴ may be each independently a substituent having 3 to 10,000, preferably, 5 to 1000 ethylene oxide groups (—CH₂CH₂O—);

R², R³, R⁵ and R⁶ may be each independently selected from (C1-C30)alkyl, (C2-C30)alkenyl, (C2-C30)alkynyl, (C6-C30)ar(C1-C30)alkyl (that is, aralkyl) or

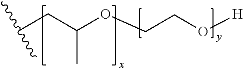

(x=0 to 1000, y=1 to 1000), —CH₂(OCH₂CH₂)ₙ-NH₂ (n=0 to 50), —CH₂(OCH₂CH₂)ₙ—OH (n=0 to 50), and —CH₂(OCH₂CH₂)ₙ—OC (=O)CH₂CH₂CH₂COOH (n=0 to 50); and

R⁷ is hydrogen or selected from (C1-C30)alkyl, (C2-C30)alkenyl, (C2-C30)alkynyl, (C6-C30)ar(C1-C30)alkyl (that is, aralkyl) or

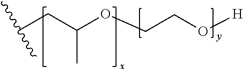

(x=0 to 1000, y=1 to 1000), —CH₂(OCH₂CH₂)ₙ—NH₂ (n=0 to 50), —CH₂(OCH₂CH₂)ₙ—OH (n=0 to 50), and —CH₂(OCH₂CH₂)ₙ—OC (=O)CH₂CH₂CH₂COOH (n=0 to 50)].

In Formulae 1 and 2, R¹ and R⁴ may be each particularly selected from the following structures:

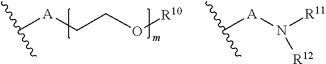

From the foregoing structures, A is a chemical bond or selected from (C1-C30)alkylene, (C2-C30)alkenylene, (C2-C30)alkynylene and (C6-C30)ar(C1-C30)alkylene; R¹⁰ is selected from hydrogen, an amino group (—NH₂), a hydroxyl group (—OH), a carboxyl group, a sulfonic acid group, a sulfuric acid group, a phosphoric acid group, a phosphorous acid group, (C1-C30)alkyl, (C2-C30)alkenyl, (C2-C30)alkynyl or (C6-C30)ar(C1-C30)alkyl (that is, aralkyl), wherein such alkyl, alkenyl, alkynyl or aralkyl may be substituted by an amino group (—NH₂) or a carboxylic acid group (COOH), m ranges from 3 to 10,000, R¹¹ is

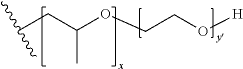

(x=0 to 1000, y′=3 to 1000), and R¹² is hydrogen or selected from (C1-C30)alkyl, (C2-C30)alkenyl, (C2-C30)alkynyl, (C6-C30)ar(C1-C30)alkyl (that is, aralkyl) or

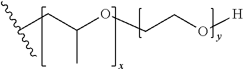

(x=0 to 1000, y=1 to 1000), —CH₂(OCH₂CH₂)ₙ—NH₂ (n=0 to 50), —CH₂(OCH₂CH₂)ₙ—OH (n=0 to 50), and —CH₂(OCH₂CH₂)ₙ—OC(=O)CH₂CH₂CH₂COOH (n=0 to 50).

FORMULA 3

R⁸—(OCH₂CH₂)_{z}—R⁹

[in Formula 3, R⁹ is selected from —(OCH₂CHCH₃)ₙ—NH₂ (n=0 to 50), —OCH₂COOH, —OC (=O)CH₂CH(SO₃H)—COOH, —OOH₂CH₂CH₂S(=O)₂OH, a carboxyl group, a sulfonic acid group, a sulfuric acid group, a phosphorous acid group and a phosphoric acid; R⁸ is hydrogen (H) or selected from (C1-C30)alkyl, (C2-C30)alkenyl, (C2-C30)alkynyl, (C6-C30)ar(C1-C30)alkyl (that is, araklyl), —CH₂COOH, —CH₂(CH₂CH₂O)ₙ—NH₂ (n=0 to 50), —CH₂(CH₂CH₂O)ₙ—OH (n=0 to 50) and —CH₂(CH₂CH₂O)ₙ—OC(=O) CH₂CH₂CH₂COOH (n=0 to 50); and z ranges from 5 to 10,000, more preferably, from 10 to 1000].

The compound used for the polysilicon polish finisher of the present invention may include, for example, a polyoxyethylene amine ether compound represented by Formula 4:

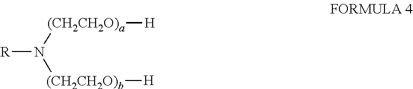

[in Formula 4, R is hydrogen (H) or selected from (C1-C30)alkyl, (C2-C30)alkenyl, (C2-C30)alkynyl, (C6-C30)ar(C1-C30)alkyl (that is, aralkyl) or

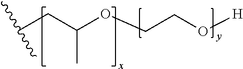

(x=0 to 1000, y=1 to 1000), wherein such alkyl, akenyl, akynyl and aralkyl may have at least one ionic functional group selected from a carboxyl group, a sulfonic acid group, a sulfuric acid group, a phosphorous acid group, a phosphoric acid group and an amine group; and (a+b) is an integer of 5 to 1000, preferably 10 to 500].

Such a polyoxyethylene amine ether compound may include, for example, polyoxyethylene laurylamine ether (CAS. NO. 61791-14-8), polyoxyethylene stearylamine ether (CAS. NO. 26635-92-7), polyoxyethylene oleylamine ether (CAS. NO. 26635-92-7), and the like. Each of these compounds is a branched compound with a molecular structure comprising at least three branches, contains nitrogen as a center atom and 5 to 1000 ethylene oxide groups, and may generate cations in an aqueous solution.

The polysilicon polish finisher of the present invention may more efficiently prevent polishing of a polysilicon film and inhibit scratches on a polysilicon film as the number of ethylene oxide groups is increased. However, the presence of too many ethylene oxide groups may undesirably increase the viscosity of the CMP composition. Therefore, the number of ethylene oxide groups preferably ranges from 3 to 10,000, more preferably from 5 to 1000, and most preferably from 10 to 300. A branched molecular structure is preferable to prevent polishing of the polysilicon film and inhibiting defects in the polysilicon film. The number of branches required for forming a molecule is preferably at least 3 and a center atom may have nitrogen or carbon. More preferably, at least two branches have ethylene oxide groups. The inventive polish finisher has also the ability to prevent polishing of a silicon nitride film, thus contributing to decrease in polishing rate thereof. Furthermore, the polish finisher must be easily washed out after polishing and, for this purpose, is advantageously dissolved in an aqueous solution and preferably comprises a functional group capable of generating ions in molecules.

An amount of the polysilicon polish finisher used in the CMP composition of the present invention may range from 0.1 to 10,000 ppm, more preferably 1 to 2,000 ppm, most preferably 10 to 1000 ppm. When an amount of the polysilicon polish finisher is too small, abilities to prevent polishing of the polysilicon film and to inhibit scratches thereon may become worse. On the other hand, if the amount is too large, the viscosity of the CMP composition may increase while a polishing rate of an insulating film is reduced.

Such an insulating film of a semiconductor substrate may include, for example: a low dielectric (low-k) film; a polysilazane (PSZ) film; a high-density plasma chemical vapor deposition (HDP-CVD) film; a plasma-enhanced TEOS (PETEOS) film; a borophosphorus silicate glass (BPSG) film; an undoped silicate glass (USG) film; a phosphorous silicate glass (PSG) film; a borosilicate glass (BSG) film; a spin-on-glass (SOG) film, and so fourth.

The CMP composition of the present invention may include abrasive particles, more particularly, at least one selected from a group consisting of silica, cerium oxide, zirconium oxide, aluminum oxide or zeolite. Cerium oxide has a lower hardness than that of silica particles or aluminum oxide particles, however, shows very high polishing rate of a silicon oxide-containing surface while having a low polysilicon polishing rate; thus, advantageously enables production of high selectivity slurries. Therefore, it is preferable to contain cerium oxide as the abrasive particles used for the CMP composition. Cerium oxide particles are formed by preparing a precursor such as cerium carbonate, cerium nitrate, cerium hydroxide, etc., through heat treatment and attrition milling using a non-reactive medium. During milling, a dispersant may be added thereto. In addition, in order to inhibit scratches during polishing, large particles may be removed by classification and filtration through sedimentation or centrifugation in a gravity field during the preparation of abrasive particles. Abrasive particles may be prepared and stored as a phase-separated dispersion and/or may be admixed with other components before further use.

Content of abrasive particles is important to induce a sufficient polishing rate. According to the desired polishing rate, the content of abrasive particles is varied. For cerium oxide used as the abrasive particles, the content may range from 0.01 to 10% by weight (referred to as “wt %”), preferably 0.03 to 3 wt %, more preferably 0.05 to 0.5 wt %. If the content is too small, the polishing rate tends to decrease. On the other hand, when the content is too large, a polished film may likely have scratches. For abrasive particles based on cerium oxide, a secondary particle diameter of each of the abrasive particles in a dispersed state preferably ranges from 10 to 1000 nm in consideration of the polishing rate and scratches, more preferably 30 to 300 nm, and most preferably 30 to 120 nm. If such a particle diameter is too small, the polishing rate is reduced. On the other hand, when the particle diameter is too large, scratches are very often formed.

Although the CMP composition of the present invention may have a broad pH range, an insulating film polishing rate is reduced or prevention of polysilicon film polishing may become worse when the pH value is too low or high. The pH range is preferably from pH 3 to 11, more preferably pH 4 to 8, and most preferably pH 5.5 to 6.8. A pH adjuster to control a pH value may include, for example: an acidic pH adjuster selected from inorganic acids such as nitric acid, hydrochloric acid, sulfuric acid, phosphoric acid, perchloric acid, etc., polymer organic acids, and organic acids; a basic pH adjuster selected from inorganic or organic bases such as KOH, ammonium hydroxide, quaternary amine hydroxide (e.g., tetramethyl ammonium hydroxide), amine, aminoalcohol, etc.; mixtures thereof, so forth. Among the foregoing, phosphoric acid may further have effects of decreasing defects in the polysilicon film. An amount of the pH adjuster may be within a predetermined range in which the pH value is sufficiently controlled and such a determined range of the amount of the pH adjuster may depend on types of pH adjusters. The amount of the pH adjuster preferably ranges from 0.001 to 10 wt % and, more preferably 0.01 to 3 wt %.

The foregoing acidic pH adjuster used in the present invention may include, for example: organic acids having carboxyl groups therein, such as acetic acid, propionic acid, succinic acid, adipic acid, lactic acid, phthalic acid, gluconic acid, citric acid, tartaric acid, malic acid, etc.; polymer organic acids such as polyacrylic acid or polyacrylic acid copolymer; mixtures thereof. When using polyorganic acids having several carboxyl groups in the inventive CMP composition, this pH adjuster may show buffering effects to inhibit pH variation. Therefore, this pH adjuster may easily control the pH during production of the CMP composition and, after production, inhibit pH variation. Accordingly, the foregoing pH adjuster is preferably used in the present invention. Polymer organic acid may also assist in preventing polysilicon polishing in addition to controlling pH. Since commercially available polyacrylic acid products often have no specified information regarding molecular weight and are generally provided and/or distributed in an aqueous state, these respective products have different contents of polyacrylic acid. An additive for a semiconductor polishing slurry according to the present invention may contain 2.5% polyacrylic acid in an aqueous solution with the viscosity of 0.8 to 20 cps. The polyacrylic acid used in the present invention may be, for example, polyacrylic acid L available from Japan Pure Chemical Co. Ltd., which has the viscosity of 1.67 cps for 2.5% aqueous solution, polyacrylic acid K available from Sigma Aldrich, which has the viscosity of 2.27 cps for 2.5% aqueous solution, and the like.

The foregoing basic pH adjuster used in the present invention may comprise organic amine or aminoalcohol. Examples of these compounds may include, ethylamine, propylamine, butylamine, diethylamine, dipropylamine, dibutylamine, triethylamine, tributylamine, monoethanolamine, diethanolamine, triethanolamine (TEA), 2-dimethylamino-2-methyl-1-propanol, 1-amino-2-propanol, 1-dimethylamino-2-propanol, 3-dimethylamino-1-propanol, 2-amino-l-propanol, 2-dimethylamino-1-propanol, 2-diethylamino-1-propanol, 2-diethylamino-1-ethanol, 2-ethylamino-1-ethanol, 1-(dimethylamino)2-propanol, N-methyldiethanolamine, N-propyldiethanolamine, N-isopropyldiethanolamine, N-(2-methylpropyl)diethanolamine, N-n-butyldiethanolamine, N-t-butylethanolamine, N-cyclohexyldiethanolamine, 2-(dimethylamino)ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl)ethanolamine, 2-amino-2-methyl-1-propanol, tris(hydroxymethyl)aminomethane or triisopropanolamine, etc., which are used alone or as a combination of two or more thereof.

In addition to the foregoing polysilicon polish finisher, abrasive particles and pH adjuster, the inventive CMP composition may optionally include a dishing inhibitor, a preservative, a lubricant, etc., if required.

Such a dishing inhibitor may be selected from: tris[2-(isopropylamino)ethyl]amine; tris[2-(ethylamino)ethyl]amine; tris[2-(methylamino)ethyl]amine; 1,2-bis(dimethylamino)ethane (BDMAE); N,N,N′,N′-tetraethylethylenediamine; N,N′-diethyl-N,N′-diethylethylenediamine; N,N-diethyl-N′,N′-dimethylethylenediamine; N,N,N′,N″,N″-pentamethyldiethylenetriamine (PMDETA); N,N′-dimethylethylenediamine; N,N′-diethylethylenediamine; N,N′-bis(2-hydroxyethyl)ethylenediamine; N,N-dimethyl-N′-ethylethylenediamine; N,N-diethyl-N′-methylethylenediamine; N,N,N′-trimethylethylenediamine; N,N,N′-triethylethylenediamine; N-ethyl-N′-methylethylenediamine; 1-(2-aminoethyl)pyrrolidine; 2-(2-(methylamino)-ethylamino)-ethanol; 1-(2-aminoethyl)piperidine; 4-(3-aminopropyl)morpholine; 4-(2-aminoethyl)morpholine; piperazine (PZ); 1-methylpiperazine; 2-methylpiperazine; 1-ethylpiperazine; 1-isopropylpiperazine; 1-butylpiperazine; 1-(2-methoxyethyl)piperazine; 1-(2-ethoxyethyl)piperazine; 1,2,4-trimethylpiperazine; 2,3,5,6-tetramethylpiperazine; 1-(2-aminoethyl)piperazine; 1-(2-hyroxyethyl)piperazine (HEPZ); 1,4-dimethylpiperazine; 2,6-dimethylpiperazine; 2,5-dimethylpiperazine; 2-piperazino ethylamine; 1,4-bis(3-aminopropyl)piperazine; 1-[2-(dimethylamino)ethyl]piperazine; N,N′-bis-(2-hyroxyethyl)-2,5-dimethylpiperazine, and mixtures thereof. In particular, BDMAE, PZ, PMDETA, and HETZ are preferably used in the present invention. An amount of the dishing inhibitor may range from 0.001 to 5 wt %, preferably 0.005 to 1 wt %, more preferably 0.01 to 0.05 wt %. If this amount is too small, dishing inhibition is insufficient. On the other hand, if the amount is too large, an insulating film polishing rate is reduced.

Examples of the lubricant used in the present invention may be glycerin and ethyleneglycol. An amount of the lubricant may range from 0.01 to 10 wt %, preferably 0.1 to 2 wt %.

If the present CMP composition contains organic acid or phosphoric acid, change over time may be caused by degradation (or decay) of the composition due to attack of microbes and/or bacteria, fungi, etc. In order to prevent such change, a preservative may be added to the CMP composition. Such a preservative is not particularly limited so long as it can inhibit degradation (or decomposition) of constituents in the slurry composition. A preservative containing an isothiazol-based compound may be used. The preservative may contain, for example, 5-chloro-2-methyl-4-isothiazolin-3-one, 2-metyl-4-isothiazolin-3-one, 2-methyl-3-isothiazolone, 1,2-benzisothiazolin-3-one, and the like. When an amount of the preservative is too small, preservation effects are insignificant. On the other hand, if this amount is too large, the preservative may prevent a polishing function of the CMP composition. Therefore, an amount of the preservative used in the inventive CMP composition may range from 0.005 to 0.2 wt % of a total weight of the CMP composition.

A preferred CMP composition of the present invention may comprise 1 to 2000 ppm of a polysilicon polish finisher and 0.01 to 10 wt % of cerium oxide-based abrasive particles, and have a pH range of 3 to 11. The CMP composition of the present invention more preferably comprises 1 to 2000 ppm of a polysilicon polish finisher, 0.03 to 3 wt % of cerium oxide particles as an abrasive, and 0.001 to 10 wt % of at least one pH adjuster selected from polymer organic acids, phosphoric acid, organic acids, aminoalcohol and mixtures thereof, and has a pH range of 4 to 8. Most preferably, the inventive CMP composition comprises 1 to 2000 ppm of a polysilicon polish finisher, 0.03 to 3 wt % of cerium oxide particles as an abrasive, 0.01 to 3 wt % of at least one pH adjuster selected from polymer organic acids, phosphoric acid, organic acids, aminoalcohol and mixtures thereof and 0.001 to 5 wt % of a dishing inhibitor, and has a pH range of 4 to 8.

Furthermore, the present invention also provides a method for polishing a semiconductor substrate having both an insulating film and a polysilicon film, using the CMP composition as described above. When using the inventive CMP composition, polishing of the polysilicon film may be prevented, in turn preferably performing a CMP process requiring a high selectivity.

The CMP composition according to the present invention may be employed in a CMP process of a substrate having both an insulating film and a polysilicon polish finisher film, so as to polish the insulating film with a high selectivity, thereby inhibiting variation in electrical characteristics of a semiconductor device.

Other features and aspects will be apparent from the following detailed description and the claims.

### DETAILED DESCRIPTION OF EMBODIMENTS

Hereinafter, the present invention will be described in detail with reference to illustrative examples. However, these examples are provided to more clearly understand technical configurations and effects of the invention and should not be construed as limiting the scope of the present invention.

### EXAMPLE 1

After preparing cerium oxide by calcinations of cerium carbonate hydrate at 800° C. for 4 hours, a small amount of dispersant as well as deionized water were added thereto, followed by grinding the mixture using a media agitation powder mill and dispersing the same. Then, after classification and filtering, deionized water was added to the filtered mixture to provide a cerium oxide dispersion having solid content of 5 wt %. The dispersion has a secondary particle size of 100 nm and pH 8.4. Three substrates having a PETEOS film, a polysilicon film and a PSZ film, respectively, were used for a polishing test. Using Poli 400 CMP equipment having a membrane type head, manufactured by G&P Tech., the polishing test was conducted under conditions of table and head revolution speeds of 93 rpm and 87 rpm, respectively, and a pressure of 300 g/cm², and the foregoing prepared CMP composition was provided at a feed speed of 200 mL/min.

Using an optical microscope to observe a surface of the polysilicon film in the substrate, an occurrence level of defects such as scratches or pits in the polysilicon film was indicated with numerals from 1 to 5. 5 means that the number of defects observed in an area of 4 cm×4cm is at least 100. Likewise, 4, 3, 2 and 1 indicate that the numbers of defects range from 100 to 50, from 50 to 20, from 20 to 10, and less than 10, respectively.

TABLE 1
Assessment results of CMP composition

| | | Surface | | Polysili- | |
|---|---|---|---|---|---|
| | | condi- | PETEOS | con | Polish- |
| | | tion of | polishing | polishing | ing |
| Test | | polysili | rate | rate | selecti |
| No. | Composition | con | (A/min) | (A/min) | vity |
| I-1 | 0.35 wt % cerium oxide, | 5 | 1991 | 135 | 15:1 |
| | pH = 7 | | | | |
| I-2 | 0.35 wt % cerium oxide, | 3 | 1723 | 25 | 69:1 |
| | 50 ppm PSAE20¹⁾, pH = 7 | | | | |
| I-3 | 0.35 wt % cerium oxide, | 2 | 1554 | 18 | 86:1 |
| | 50 ppm PSAE20, 0.1% | | | | |
| | phosphoric acid, pH = 7 | | | | |
| I-4 | 0.35 wt % cerium oxide, | 1 | 2065 | 10 | 206:1 |
| | 50 ppm PSAE20, | | | | |
| | 0.03 wt % | | | | |
| | L²⁾, 0.03 wt % BDMAE³⁾ | | | | |
| | 0.015 wt % citric acid, | | | | |
| | 0.09 wt % TEA⁴⁾, pH = 7 | | | | |

¹⁾PSAE 20: polyoxyethylene stearyl amine ether (a + b = 20) 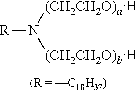
²⁾L: polyacrylic acid (product available from Japan Pure Chemical Co. Ltd., which has the viscosity of 1.67 cps in 2.5% aqueous solution)
³⁾BDMAE: 1,2-bis(dimethylamino)ethane
⁴⁾TEA: Triethanoamine

From results shown in Table 1, it was found that the composition containing the polysilicon polish finisher as well as cerium oxide rapidly reduces a polysilicon polishing rate which in turn relatively increases a polishing selectivity relative to a silicon oxide film, compared to using cerium oxide alone. Moreover, it can be seen that adding phosphoric acid or other additives such as polyacrylic acid to the composition may further reduce the polysilicon polishing rate and inhibit occurrence of surface defects in the polysilicon film.

### EXAMPLE 2

### Assessment of Polysilicon Polish Finisher

As shown in the following Table 2, various slurries with 0.4 wt % cerium oxide, 0.08 wt % L, 0.03 wt % BDMAE, 0.015 wt % citric acid and 0.09 wt % TEA, as well as specific polysilicon polish finishers listed in the same table as an additive, were prepared. Herein, the slurries have a constant pH 6.75. Polishing conditions and assessment ways executed in this example are substantially the same as described in Example 1.

TABLE 2

| | | Average | | | | |
|---|---|---|---|---|---|---|
| | | number | | | | |
| | | of | Polysili- | Surface | | |
| | | ethylene | con | state | PETEOS | Polish |
| | | oxide | polishing | of | polishing | ing |
| Test | Additive and amount | group in | rate | polysili- | rate | selecti- |
| No. | thereof | additive | (A/min) | con | (A/min) | vity |
| 2-1 | Polyoyethylene | 15 | 12 | 1 | 2349 | 196:1 |
| | stearyl amine ether | | | | | |
| | (n + m = 15) 20 ppm | | | | | |
| 2-2 | 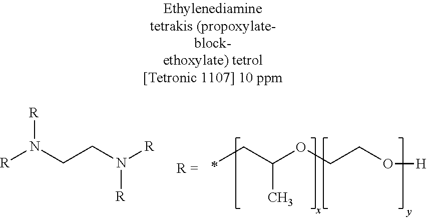 | 170-340 | 19 | 2 | 2207 | 116:1 |
| 2-3 | 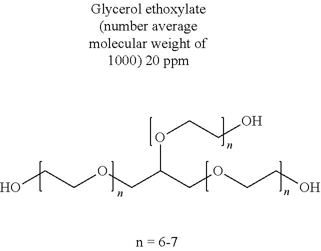 | 21 | 21 | 3 | 2151 | 102:1 |
| 2-4 | 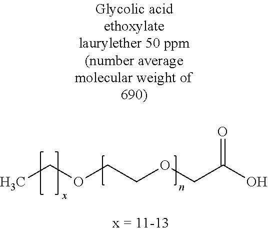 | 10 | 17 | 2 | 1853 | 109:1 |
| 2-5 | PSAE20 40 ppm + | 15 | 12 | 1 | 2385 | 199:1 |
| | polyoxyethylene | | | | | |
| | laurylamine (n + m = 15) | | | | | |
| | 10 ppm | | | | | |
| 2-6 | PSAE20 10 ppm + | 20 | 15 | 2 | 2199 | 147:1 |
| | Glycerol ethoxylate | | | | | |
| | 50 ppm | | | | | |
| 2-7 | PSAE20 50 ppm + | 18 | 13 | 1 | 2306 | 177:1 |
| | Glycolic acid | | | | | |
| | ethoxylate | | | | | |
| | laurylether 10 ppm | | | | | |
| 2-8 | Polyethyleneglyco | 22 | 31 | 5 | 2095 | 68:1 |
| | (number average | | | | | |
| | molecular weight of | | | | | |
| | 1000) 20 ppm | | | | | |

From the results of Table 2, it was found that the CMP composition containing the polysilicon polish finisher of the present invention shows remarkably reduced polysilicon film polishing rate and favorable surface state of the polysilicon film after polishing. In contrast, a control containing a linear polyethyleneglycol (Test No. 2-8) demonstrates a number of pit defects on a polysilicon surface and relatively a lower polishing selectivity.

### EXAMPLE 3

### Polishing Features Depending on Content of Polysilicon Polish Finisher

Polishing features of a PSZ film depending on the content of the polysilicon polish finisher were determined. As shown in the following Table 3, various slurries containing 0.45 wt % cerium oxide, 0.08 wt % L, 0.03 wt % BDMAE, 0.015 wt % citric acid and 0.09 wt % TEA, as well as PSAE20 as a polysilicon polish finisher with different contents listed in Table 3, were prepared. Herein, the slurries have a constant pH of 6.75. Polishing conditions and assessment means executed in this example are substantially the same as described in Example 1.

TABLE 3
Effects of PSAE20 content

| | | PSZ | | | |
|---|---|---|---|---|---|
| | | polishing | Polysilicon | | Surface |
| Test | Content of | rate | polishing | Polishing | state of |
| No. | PSAE20 | (A/min) | rate (A/min) | selectivity | polysilicon |
| 3-1 | 10 ppm | 3475 | 26 | 134:1 | 3 |
| 3-2 | 20 ppm | 3336 | 20 | 167:1 | 2 |
| 3-3 | 50 ppm | 3399 | 15 | 227:1 | 1 |
| 3-4 | 100 ppm | 3076 | 12 | 256:1 | 1 |
| 3-5 | 200 ppm | 2853 | 10 | 285:1 | 1 |

From the results of Table 3, it was found that the polysilicon polishing rate is low but defects are undesirably formed on the polysilicon surface when a content of the polysilicon polish finisher is small. It can be seen that, if a content of the polysilicon polish finisher increases, occurrence of surface defects may be improved while a PSZ film polishing rate is reduced.

### EXAMPLE 4

### Assessment of Silicon Nitride Film Polishing Rate

For a silicon nitride film, a polishing rate and a polishing selectivity were measured.

TABLE 4
Silicon nitride polishing rate and
polishing selectivity

| | | | Silicon | |
|---|---|---|---|---|
| | | PETEOS | nitride | |
| | | polishing | polishing | |
| Test | | rate | rate | Polishing |
| No. | Composition | (A/min) | (A/min) | selectivity |
| 4-1 | 0.35 wt % cerium oxide, | 1988 | 43 | 46:1 |
| | 0.08 wt % L, 0.03 wt % | | | |
| | BDMAE, 0.015 wt % citric | | | |
| | acid, 0.09 wt % TEA, | | | |
| | pH = 6.75 | | | |
| 4-2 | 0.35 wt % cerium oxide, | 2034 | 23 | 81:1 |
| | 50 ppm PSAE20, 0.08 wt % | | | |
| | L, 0.03 wt % BDMAE, | | | |
| | 0.015 wt % citric acid, | | | |
| | 0.09 wt % TEA, pH = 6.75 | | | |

It can be seen that the polysilicon polish finisher used in the present invention has additional functions to reduce a silicon nitride polishing rate which in turn improves a polishing selectivity, while the CMP composition of the present invention also demonstrates noticeably excellent effects in a polishing process using silicon nitride as a polish finisher film.

1. A chemical mechanical polishing (‘CMP’) composition for polishing an insulating film, comprising:
(i) a polysilicon polish finisher selected from 1) a compound that has a branched molecule with a molecular structure comprising at least three branches, and contains nitrogen or carbon as a center atom and at least three ethylene oxide groups (—CH₂CH₂O—) in a molecule, and its salt or a mixture thereof, 2) a compound having at least one functional group to be ionized in aqueous solution as well as at least three ethylene oxide groups (—CH₂CH₂O—), and its salt or a mixture thereof, or a combination of 1) and 2); and
(ii) at least one type of abrasive particles selected from silica, cerium oxide, zirconium oxide, aluminum oxide or zeolite.

2. The CMP composition of claim 1, wherein the composition includes the polysilicon polish finisher in an amount of 0.1 ppm to 10,000 ppm and cerium oxide-based abrasive particles in an amount of 0.01 to 10 wt % relative to a total weight of the CMP composition, and has a pH range of 3 to 11.

3. The CMP composition of claim 2, wherein the polysilicon polish finisher is selected from compounds represented by Formulae 1 to 3 and mixture thereof: 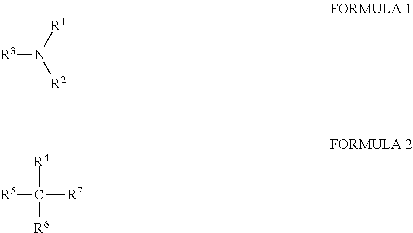
[wherein R¹ and R⁴ may be each independently a substituent having 3 to 10,000 ethylene oxide groups (—CH₂CH₂O—) in Formulae 1 and 2;
R², R³, R⁵ and R⁶ may be each independently selected from (C1-C30)alkyl, (C2-C30)alkenyl, (C2-C30)alkynyl, (C6-C30)ar(C1-C30)alkyl or 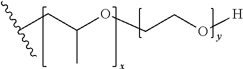
(x=0 to 1000, y=1 to 1000), —CH₂(OCH₂CH₂)_{N}—NH₂ (n=0 to 50), —CH₂(OCH₂CH₂)_{N}—OH (n=0 to 50), and —CH₂(OCH₂CH₂)₂—oC(=O)CH₂CH₂CH₂COOH (n=0 to 50); and
R⁷ is hydrogen or selected from (C1-C30)alkyl, (C2-C30)alkenyl, (C2-C30)alkynyl, (C6-C30)ar(C1-C30)alkyl or 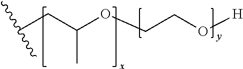
(x=0 to 1000, y=1 to 1000), —CH₂(OCH₂CH₂)_{N}—NH₂ (n=0 to 50), —CH₂(OCH₂CH₂)_{N}—OH (n=0 to 50), and —CH₂(OCH₂CH₂)_{N}—OC(=O)CH₂CH₂CH₂COOH (n=0 to 50)],
FORMULA 3
R⁸—(OCH₂CH₂)_{z}—R⁹
[wherein R⁹ is selected from —(OCH₂CHCH₃)ₙ—NH₂ (n=0 to 50), —OCH₂COOH, —OC(=O)CH₂CH(SO₃H)—COON, —OCH₂CH₂CH₂S(=O)₂OH, a carboxyl group, a sulfonic acid group, a sulfuric acid group, a phosphorous acid group and a phosphoric acid; R⁸ is hydrogen (H) or selected from (C1-C30)alkyl, (C2-C30)alkenyl, (C2-C30)alkynyl, (C6-C30)ar(C1 -C30)alkyl, —CH₂COOH, —CH₂(CH₂CH₂O)ₙ—NH₂ (n=0 to 50), —CH₂(CH₂CH₂O)ₙ—OH (n=0 to 50) and —CH₂(CH₂CH₂O)ₙ—OC(=O)CH₂CH₂CH₂COOH (n=0 to 50); and z ranges from 5 to 10,000].

4. The CMP composition of claim 2, wherein the polysilicon polish finisher is selected from a compound having a branched molecule with a molecular structure comprising at least three branches, nitrogen or carbon as a center atom, 5 to 1000 ethylene oxide groups (—CH₂CH₂O—) in a molecule and at least one functional group ionized in aqueous solution, and its salt and mixtures thereof.

5. The CMP composition of claim 2, wherein the polysilicon polish finisher is selected from compounds represented by Formula 4 and mixtures thereof: 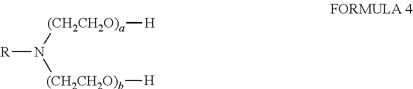
[wherein R is hydrogen (H) or selected from (C1-C30)alkyl, (C2-C30)alkenyl, (C2-C30)alkynyl, (C6-C30)ar(C1-C30)alkyl and 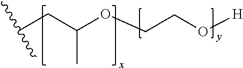
(x=0 to 1000, y=1 to 1000), wherein such alkyl, akenyl, akynyl and aralkyl may have at least one ionic functional group selected from a carboxyl group, a sulfonic acid group, a sulfuric acid group, a phosphorous acid group, a phosphoric acid group and an amine group; and (a+b) is an integer of 5 to 1000].

6. The CMP composition of claim 3, wherein the abrasive particles are cerium oxide having a secondary particle diameter of 10 to 1000 nm in a dispersion.

7. The CMP composition of claim 3, wherein the pH value is regulated using at least one of: an acidic pH adjuster selected from nitric acid, hydrochloric acid, sulfuric acid, phosphoric acid, perchloric acid, polymer organic acid and organic acids; and a basic pH adjuster selected from potassium hydroxide, ammonium hydroxide, quaternary amine hydroxide, amine and aminoalcohol.

8. The CMP composition of claim 7, wherein the acidic pH adjuster is selected from a group consisting of nitric acid, phosphoric acid, acetic acid, propionic acid, succinic acid, adipic acid, lactic acid, phthalic acid, gluconic acid, citric acid, tartaric acid, maleic acid, polyacrylic acid, polyacrylic acid copolymer, and mixtures thereof.

9. The CO composition of claim 7, wherein the basic pH adjuster is selected from a group consisting of ethylamine, propylamine, butylamine, diethylamine, dipropylamine, dibutylamine, triethylamine, tributylamine, monoethanolamine, diethanolamine, triethanolamine, 2-dimethylamino-2-methyl-1-propanol, 1-amino-2-propanol, 1-dimethylamino-2-propanol, 3-dimethylamino-1-propanol, 2-amino-1-propanol, 2-dimethylamino-1-propanol, 2-diethylamino-1-propanol, 2-diethylamino-1-ethanol, 2-ethylaino-1-ethanol, 1-(dimethylamino)-2-propanol, N-methyldiethanolamine, N-propyldiethanolamine, N-isopropyldiethanolamine, N-(2-methylpropyl)diethanolamine, N-n-butyldiethanolamine, N-t-butylethanolamine, N-cyclohexyldiethanolamine, 2-(2-methylamino)ethanol, 2-diethylaminoethanol, 2-dipropylaminoethanol, 2-butylaminoethanol, 2-t-butylaminoethanol, 2-cycloaminoethanol, 2-amino-2-pentanol, 2-[bis(2-hydroxyethyl)amino]-2-methyl-1-propanol, 2-[bis(2-hydroxyethyl)amino]-2-propanol, N,N-bis(2-hydroxypropyl)ethanolamine, 2-amino-2-methyl-1-propanol, tris(hydroxymethyl)aminomethane, triisopropanolamine and mixture thereof.

10. The CMP composition of claim 7, wherein the CMP composition further contains at least one selected from a dishing inhibitor, a lubricant and a preservative.

11. The CMP composition of claim 10, wherein the dishing inhibitor is selected from a group consisting of: tris[2-(isopropylamino)ethyl]amine; tris[2-(ethylamino)ethyl]amine; tris[2-(methylamino)ethyl]amine; 1,2-bis(dimethylamino) ethane; N,N,N′,N′-tetraethylethylenediamine; N,N′-diethyl-N,N′-diethylethylenediamine; N,N-diethyl-N′,N′-dimethylethylenediamine; N,N,N′,N″,N″-pentamethyldiethylenetriamine; N,N′-dimethylethylenediamine; N,N′-diethylethylenediamine; N,N′-bis(2-hydroxyethyl)ethylenediamine; N,N-dimethyl-N′-ethylethylenediamine; N,N-diethyl-N′-methylethylenediamine; N,N,N′-trimethylethylenediamine; N,N,N′-triethylethylenediamine; N-ethyl-N′-methylethylenediamine; 1-(2-aminoethyl)pyrrolidine; 2-(2-(methylamino)-ethylamino)-ethanol; 1-(2-aminoethyl)piperidine; 4-(3-aminopropyl)morpholine; 4-(2-aminoethyl)morpholine; piperazine; 1-methylpiperazine; 2-methylpiperazine; 1-ethylpiperazine; 1-isopropylpiperazine; 1-butylpiperazine; 1-(2-methoxyethyl)piperazine; 1-(2-ethoxyethyl)piperazine; 1,2,4-trimethylpiperazine; 2,3,5,6-tetramethylpiperazine; 1-(2-aminoethyl)piperazine; 1-(2-hyroxyethyl)piperazine; 1,4-dimethylpiperazine; 2,6-dimethylpiperazine; 2,5-dimethylpiperazine; 2-piperazinoethylamine; 1,4-bis(3-aminopropyl)piperazine; 1-[2-(dimethylamino)ethyl]piperazine; N,N′-bis-(2-hyroxyethyl)-2,5-dimethylpiperazine, and mixtures thereof.

12. The CMP composition of claim 7, wherein the composition contains the polysilicon polish finisher in an amount of 1 to 2000 ppm, cerium oxide based abrasive particles in an amount of 0.03 to 3 wt % and at least one pH adjuster selected from acidic pH adjusters and basic pH adjusters in an amount of 0.001 to 10 wt % relative to a total weight of the CMP composition, and has a pH range of 4 to 8.

13. The CMP composition of claim 10, wherein the composition contains the polysilicon polish finisher in an amount of 1 to 2000 ppm, cerium oxide-based abrasive particles in an amount of 0.03 to 3 wt %, at least one pH adjuster selected from polymer organic acid, phosphoric acid, organic acid, aminoalcohol and mixtures thereof in an amount of 0.01 to 3 wt % and a dishing inhibitor in an amount of 0.001 to 5 wt % relative to a total weight of the CMP composition, and has a pH range of 4 to 8.

14. A method for polishing a semiconductor substrate having an insulating film, using the CMP composition of claim 1.
